(19) United States
(12) Patent Application Publication
(10) Pub. No.: US 2020/0098409 A1
(43) Pub. Date: Mar. 26, 2020

(54) MAGNETIC RANDOM ACCESS MEMORY (MRAM) INTEGRATION

(71) Applicant: QUALCOMM Incorporated, San Diego, CA (US)

(72) Inventors: Xia LI, San Diego, CA (US); Jianguo YAO, Londonderry, NH (US)

(21) Appl. No.: 16/404,549

(22) Filed: May 6, 2019

Related U.S. Application Data
(60) Provisional application No. 62/735,640, filed on Sep. 24, 2018.

(51) Int. Cl. G11C 11/16; H01L 43/08; H01L 27/22

(52) U.S. Cl. CPC G11C 11/1655; G11C 11/161; G11C 11/1673; H01L 27/228; G11C 11/1657; G11C 11/1659; H01L 43/08; G11C 11/1675

(57) ABSTRACT

A magnetic random access memory (MRAM) array is described. The MRAM array includes bit cells, and each bit cell includes a magnetic tunnel junction (MTJ). The MTJ include a barrier layer between a free layer and a pinned layer. In addition the bit cells are shorted together. The MRAM array also includes wordline (WL) devices, each coupled to one of the bit cells. The MRAM array further includes a tristate bit line (BL) driver coupled to each of the bit cells. The MRAM array also includes a tristate source line (SL) driver coupled to each of the bit cells via the WL devices.

### CROSS-REFERENCE TO RELATED APPLICATION

The present application claims the benefit of U.S. Provisional Patent Application No. 62/735,640, filed on Sep. 24, 2018, and titled “MAGNETIC RANDOM ACCESS MEMORY (MRAM) INTEGRATION,” the disclosure of which is expressly incorporated by reference in its entirety.

### BACKGROUND

### Field

Certain aspects of the present disclosure generally relate to magnetic tunneling junction (MTJ) devices, and more particularly to high performance magnetic random access memory (MRAM) integration.

### Background

Unlike conventional random access memory (RAM) chip technologies, in magnetic RAM (MRAM), data is stored by magnetization of storage elements. The basic structure of the storage elements consists of metallic ferromagnetic layers separated by a thin tunneling barrier. One of the ferromagnetic layers (e.g., the ferromagnetic layer underneath the barrier) has a magnetization that is fixed in a particular direction, and is commonly referred to as the reference layer. The other ferromagnetic layers (e.g., the ferromagnetic layer above the tunneling barrier) have a magnetization direction that may be altered to represent either a “1” or a “0,” and are commonly referred to as the free layers.

For example, a “1” may be represented when the free layer magnetization is anti-parallel to the fixed layer magnetization. In addition, a “0” may be represented when the free layer magnetization is parallel to the fixed layer magnetization or vice versa. One such device having a fixed layer, a tunneling layer, and a free layer is a magnetic tunnel junction (MTJ). The electrical resistance of an MTJ depends on whether the free layer magnetization and fixed layer magnetization are parallel or anti-parallel to each other. A memory device such as MRAM is built from an array of individually addressable MTJs.

To write data in a conventional MRAM, a write current, which exceeds a critical switching current, is applied through an MTJ. Application of a write current that exceeds the critical switching current changes the magnetization direction of the free layer. When the write current flows in a first direction, the MTJ may be placed into or remain in a first state in which its free layer magnetization direction and fixed layer magnetization direction are aligned in a parallel orientation. When the write current flows in a second direction, opposite to the first direction, the MTJ may be placed into or remain in a second state in which its free layer magnetization and fixed layer magnetization are in an anti-parallel orientation.

To read data in a conventional MRAM, a read current may flow through the MTJ via the same current path used to write data in the MTJ. If the magnetizations of the MTJ's free layer and fixed layer are oriented parallel to each other, the MTJ presents a parallel resistance. If the parallel resistance is different than a resistance (anti-parallel), the MTJ would present as if the magnetizations of the free layer and the fixed layer were in an anti-parallel orientation. In a conventional MRAM, two distinct states are defined by these two different resistances of an MTJ in a bit cell of the MRAM. The two different resistances indicate whether a logic “0” or a logic “1” value is stored by the MTJ.

MRAM embedded within logic circuits may operate at a comparable or higher speed than off-chip dynamic random access memory (DRAM). Unfortunately, scaling and integration of MRAM are limited by a wordline (WL) driver size and a WL driver current. In particular, an MRAM bit cell size as well as an MTJ critical dimension (CD) are limited by the WL device drive current. An MTJ size is also dominated by the WL driver size. In addition, MRAM speed performance and reliability are limited by the WL drive current.

### SUMMARY

A magnetic random access memory (MRAM) array is described. The MRAM array includes bit cells, and each bit cell includes a magnetic tunnel junction (MTJ). The MTJ include a barrier layer between a free layer and a pinned layer. In addition the bit cells are shorted together. The MRAM array also includes wordline (WL) devices, each coupled to one of the bit cells. The MRAM array further includes a tristate bit line (BL) driver coupled to each of the bit cells. The MRAM array also includes a tristate source line (SL) driver coupled to each of the bit cells via the WL devices.

A method of operating a magnetic random access memory (MRAM) array is described. The method includes tristating, with first signals, bit cells of the MRAM array to activate a selected branch of the MRAM array. The method also includes tristating, with second signals, wordline (WL) devices of the MRAM array to share a selected portion of the WL devices with the selected branch of the MRAM array.

A magnetic random access memory (MRAM) array is described. The MRAM array includes bit cells, and each bit cell includes a magnetic tunnel junction (MTJ). The MTJ include a barrier layer between a free layer and a pinned layer. In addition the bit cells are shorted together. The MRAM array also includes means for driving wordlines of the MRAM array, coupled to the bit cells. The MRAM array further includes a tristate bit line (BL) driver coupled to each of the bit cells. The MRAM array also includes a tristate source line (SL) driver coupled to each of the bit cells via the means for driving wordlines of the MRAM array.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a diagram of a magnetic tunnel junction (MTJ) device connected to an access transistor.

FIG. 2 is a conceptual diagram of a conventional spin-transfer torque magnetic random access memory (STT-MRAM) cell including an MTJ.

FIG. 3 is a cross-sectional diagram illustrating a conventional perpendicular magnetic tunnel junction (pMTJ) stack structure.

FIG. 4 is a block diagram of a magnetic random access memory (MRAM) array configured for high performance integration, according to aspects of the present disclosure.

FIGS. 5A and 5B are block diagrams illustrating shorting of a magnetic tunnel junction (MTJ) bottom electrode, according to aspects of the present disclosure.

FIG. 6A is a block diagram of a magnetic random access memory (MRAM) array configured for a first write operation, according to aspects of the present disclosure.

FIG. 6B is a block diagram of a magnetic random access memory (MRAM) array configured for a second write operation, according to aspects of the present disclosure.

FIG. 7 is a block diagram of a magnetic random access memory (MRAM) array configured for a read operation, according to aspects of the present disclosure.

FIG. 8 is a block diagram of a magnetic random access memory (MRAM) array configured for high performance integration, according to aspects of the present disclosure.

FIG. 9A is a block diagram of a magnetic random access memory (MRAM) array configured for a first write operation, according to aspects of the present disclosure.

FIG. 9B is a block diagram of a magnetic random access memory (MRAM) array configured for a second write operation, according to aspects of the present disclosure.

FIG. 10 is a block diagram of a magnetic random access memory (MRAM) array configured for a read operation, according to aspects of the present disclosure.

FIG. 11 is a process flow diagram illustrating a method of operating a magnetic random access memory (MRAM) array of bit cells, according to aspects of the present disclosure.

FIG. 12 is a block diagram showing an exemplary wireless communications system in which a configuration of the disclosure may be advantageously employed.

FIG. 13 is a block diagram illustrating a design workstation used for circuit, layout, and logic design of a semiconductor component according to one aspect of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Unlike conventional random access memory (RAM) chip technologies, in magnetic RAM (MRAM), data is stored by magnetization of storage elements. For example, a “1” may be represented when a free layer magnetization is anti-parallel to a fixed layer magnetization of the MRAM. In addition, a “0” may be represented when the free layer magnetization is parallel to the fixed layer magnetization or vice versa. A free layer and fixed layer magnetic moment can be a horizontal direction against the free or fixed layer plane (called in-plane) or a vertical direction against the free or fixed layer plane (called perpendicular). One such device having a fixed layer, a tunneling layer, and a free layer is a magnetic tunnel junction (MTJ). The electrical resistance of an MTJ depends on whether the free layer magnetization and fixed layer magnetization are parallel or anti-parallel to each other. An in-plane MTJ may be referred to as an iMTJ. In addition, a perpendicular MTJ may be referred to as a pMTJ. A memory device such as MRAM is built from an array of individually addressable MTJs. According to this nomenclature, an iMTJ forms an iMRAM, and a pMTJ forms a pMRAM.

Various aspects of the disclosure provide techniques for high performance magnetic random access memory (MRAM) integration. The process flow for integrating high performance MRAM may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably unless such interchanging would tax credulity.

As described, the back-end-of-line interconnect layers may refer to the conductive interconnect layers (e.g., metal one (M1), metal two (M2), metal three (M3), etc.) for electrically coupling to front-end-of-line active devices of an integrated circuit. The back-end-of-line interconnect layers may electrically couple to middle-of-line interconnect layers, for example, connecting M1/M0 to an oxide diffusion (OD) or gate layer of an integrated circuit via a contact. A back-end-of-line second via (V2) may connect M2 to M3 or others of the back-end-of-line interconnect layers. The front-end-of-line processes may include the set of process steps that form the active devices, such as transistors, capacitors, and diodes. The front-end-of-line processes include ion implantation, anneals, oxidation, CVD (chemical vapor deposition) or ALD (atomic layer deposition), etching, CM′ (chemical mechanical polishing), and epitaxy.

The middle-of-line processes may include the set of process steps that enable connection of the transistors to the back-end-of-line interconnects (e.g., M1, . . . , M8). These steps include silicidation and contact formation as well as stress introduction. The back-end-of-line processes may include the set of process steps that form the interconnect that ties the independent transistors and form circuits. Currently, copper and aluminum are used to form the interconnects, but with further development of the technology, other conductive material may be used.

High performance MRAM integration is described, in which the MRAM is built from an array of individually addressable MTJs. In aspects of the present disclosure, an MRAM array includes MTJ bit cells. In one configuration, each of the bit cells is composed of an MTJ including a barrier layer between a free layer and a pinned (or fixed) layer. The MRAM array also includes wordline (WL) devices, each coupled to a bottom electrode of one of the bit cells. In this configuration, the bottom electrode of each of the bit cells is electrically shorted. The MRAM array also includes a tristate bit line (BL) driver coupled to each of the bit cells. The MRAM array further includes a tristate source line (SL) driver coupled to each of the bit cells.

In aspects of the present disclosure, WL devices are shared by a selected branch of the MRAM array. Selecting the MRAM branch to share the WL devices is performed by driving tristate values of the tristate BL and SL drivers. The shared WL devices enable a variety of configurations. An MRAM bitcell is usually configured as 1T (e.g., one WL access transistor) 1J (one MTJ) bitcell. A sized of this MRAM bitcell is dominated by a WL access transistor size which provides a switching current of the MTJ. So the WL access transistor size (e.g., width) is defined by an MTJ switching current. For example, an MRAM array may be configured for high performance and reliability. A high performance MRAM involves a high drive current and a large access transistor size. Alternatively, the MRAM array may be configured using a reduced bit cell size with limited MRAM integration reliability using WL and/or BL/SL voltage overdrive. In a configuration using a same (e.g., 1×) bit cell size, high speed performance as well as a large sense window size are realized with no reliability degradation. WL overdrive and SL overdrive may be applied to increase a small MTJ critical dimension (CD), speed, and performance.

In a configuration using a reduced (e.g., less than one-third (⅓) bit cell size, similar speed, performance, and sense window are achieved with limited reliability. The limited reliability may refer to, for example, a time-dependent dielectric breakdown (TTBD) as well as a high-temperature operating life (HTOL) of the WL devices. In addition, WL overdrive and SL overdrive may be applied to increase speed and performance. This configuration may use N-type metal oxide semiconductor (NMOS) or P-type MOS (PMOS) transistors as the wordline devices.

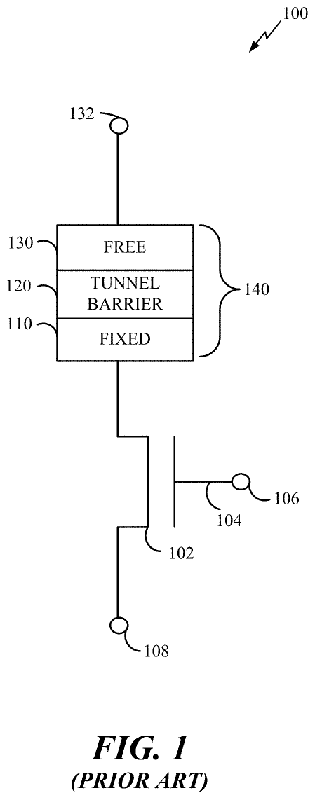

FIG. 1 illustrates a memory cell 100 of a memory device including a magnetic tunnel junction (MTJ) 140 coupled to an access transistor 102. The memory device may be a magnetic random access memory (MRAM) device that is built from an array of individually addressable MTJs. An MTJ stack may include a free layer, a fixed layer and a tunnel barrier layer there between as well as one or more ferromagnetic (or anti-ferromagnetic) layers. Representatively, a free layer 130 of the MTJ 140 is coupled to a bit line 132. The access transistor 102 is coupled between a fixed layer 110 of the MTJ 140 and a fixed potential node 108. A tunnel barrier layer 120 is coupled between the fixed layer 110 and the free layer 130. The access transistor 102 includes a gate 104 coupled to a wordline 106.

Synthetic anti-ferromagnetic materials may form the fixed layer 110 and the free layer 130. For example, the fixed layer 110 may include multiple material layers including a cobalt-iron-boron (CoFeB) layer, a ruthenium (Ru) layer and a cobalt-iron (CoFe) layer. In addition, the free layer 130 may also include multiple material layers including a cobalt-iron-boron (CoFeB) layer, a ruthenium (Ru) layer and a cobalt-iron (CoFe) layer. Further, the tunnel barrier layer 120 may be magnesium oxide (MgO).

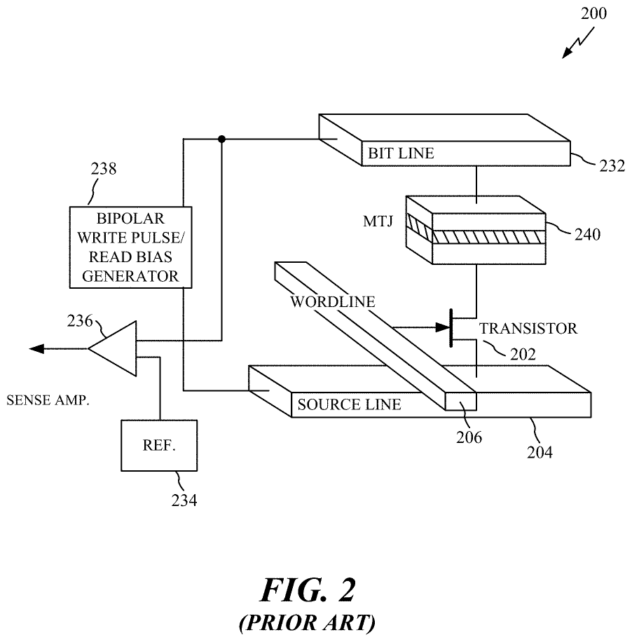

FIG. 2 illustrates a conventional spin-transfer torque magnetic random access memory (STT-MRAM) bit cell 200. The STT-MRAM bit cell 200 includes a magnetic tunnel junction (MTJ) storage element 240, a transistor 202, a bit line 232, and a wordline 206. The MTJ storage element 240 is formed, for example, from at least two anti-ferromagnetic layers (a pinned layer and a free layer), each of which can hold a magnetic field or polarization, separated by a thin non-magnetic insulating layer (tunneling barrier). Electrons from the two ferromagnetic layers can tunnel through the tunneling barrier due to a tunneling effect under a bias voltage applied to the ferromagnetic layers. The magnetic polarization of the free layer can be reversed so that the polarity of the pinned layer and the free layer are either substantially aligned or opposite. The resistance of the electrical path through the MTJ varies depending on the alignment of the polarizations of the pinned and free layers. This variance in resistance may program and read the bit cell 200. The STT-MRAM bit cell 200 and peripheral circuits also include a source line 204, a sense amplifier 236, read/write circuitry 238, and a bit line reference 234

Materials that form a perpendicular magnetic tunnel junction (pMTJ) of a pMRAM generally exhibit high tunneling magneto resistance (TMR), high perpendicular magnetic anisotropy (PMA) and good data retention. pMTJ structures may be made in a perpendicular orientation, referred to as perpendicular magnetic tunnel junction (pMTJ) devices. A stack of materials (e.g., cobalt-iron-boron (CoFeB) materials) with a dielectric barrier layer (e.g., magnesium oxide (MgO)) may be employed in a pMTJ structure. A pMTJ structure including a stack of materials (e.g., CoFeB/MgO/CoFeB) has been considered for MRAM structures.

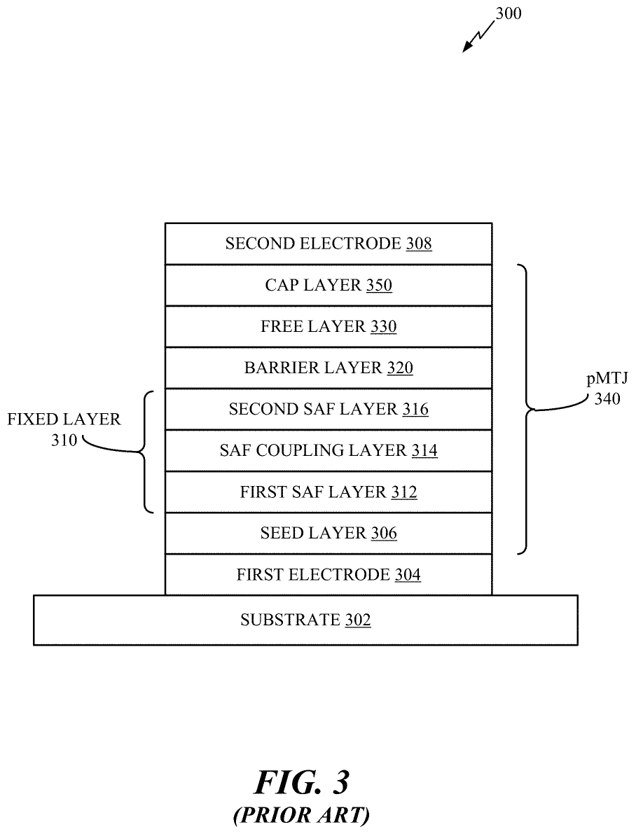

FIG. 3 illustrates a cross-sectional view of a conventional perpendicular magnetic tunnel junction (pMTJ) structure. Representatively, an MTJ structure 300, which is shown as a pMTJ structure 340 in FIG. 3, is formed on a substrate 302. The MTJ structure 300 may be formed on a semiconductor substrate, such as a silicon substrate, or any other alternative suitable substrate material. The MTJ structure 300 may include a first electrode 304, a seed layer 306, and a fixed layer 310. The fixed layer 310 includes a first synthetic antiferromagnetic (SAF) layer 312, a SAF coupling layer 314, and a second SAF layer 316. The MTJ structure 300 also includes a barrier layer 320, a free layer 330, a cap layer 350 (also known as a capping layer), and a second electrode 308. The MTJ structure 300 may be a part of various types of devices, such as a semiconductor memory device (e.g., MRAM).

In this configuration, the first electrode 304 (e.g., bottom electrode) and the second electrode 308 (e.g., top electrode) include conductive materials (e.g., tantalum (Ta)). In other configurations, the first electrode 304 and/or second electrode 308 may include other appropriate materials, including but not limited to platinum (Pt), copper (Cu), gold (Au), aluminum (Al), or other like conductive materials. The first electrode 304 and the second electrode 308 may employ different materials within the MTJ structure 300.

A seed layer 306 is formed on the first electrode 304. The seed layer 306 may provide a mechanical and crystalline substrate for the first SAF layer 312. The seed layer 306 may be a compound material, including but not limited to, nickel chromium (NiCr), nickel iron (NiFe), nickel iron chromium (NiFeCr), or other suitable materials for the seed layer 306. When the seed layer 306 is grown or otherwise coupled to the first electrode 304, a smooth and dense crystalline structure results in the seed layer 306. In this configuration, the seed layer 306 promotes growth of subsequently formed layers in the MTJ structure 300 according to a specific crystalline orientation. The crystalline structure of the seed layer 306 may be selected to be any crystal orientation within the Miller index notation system, but is often chosen to be in the (111) crystal orientation.

A first SAF layer 312 is formed on the seed layer 306. The first SAF layer 312 includes a multilayer stack of materials formed on the seed layer 306, which may be referred to herein as a first anti-parallel pinned layer (AP1). The multilayer stack of materials in the first SAF layer 312 may be an anti-ferromagnetic material or a combination of materials to create an anti-ferromagnetic moment in the first SAF layer 312. The multilayer stack of materials forming the first SAF layer 312 include, but are not limited to, cobalt (Co), cobalt in combination with other materials such as nickel (Ni), platinum (Pt), or palladium (Pd), or other like ferromagnetic materials.

An SAF coupling layer 314 is formed on the first SAF layer 312, and promotes magnetic coupling between the first SAF layer 312 and a second SAF layer 316. The second SAF layer 316 has a magnetic orientation anti-parallel with the first SAF layer 312. The SAF coupling layer 314 includes material that aides in this coupling including, but not limited to, ruthenium (Ru), tantalum (Ta), gadolinium (Gd), platinum (Pt), hafnium (Hf), osmium (Os), rhodium (Rh), niobium (Nb), terbium (Tb), or other like materials. The SAF coupling layer 314 may also include materials to provide mechanical and/or crystalline structural support for the first SAF layer 312 and the second SAF layer 316.

The second SAF layer 316 is formed on the SAF coupling layer 314. The second SAF layer 316 may have similar materials as the first SAF layer 312, but may include other materials. The combination of the first SAF layer 312, the SAF coupling layer 314, and the second SAF layer 316 forms the fixed layer 310 including the SAF reference layers, which is often referred to as a “pinned layer” in the MTJ structure 300. The fixed layer 310 fixes, or pins, the magnetization direction of the SAF reference layers (e.g., 312, 314, 316) through anti-ferromagnetic coupling. As described herein, the second SAF layer 316 may be referred to as a second anti-parallel pinned layer (AP2). In this arrangement, the first SAF layer 312 may be referred to as a first anti-parallel pinned layer (AP1) that is separated from the second anti-parallel pinned layer (AP2) by the SAF coupling layer 314 to form the fixed layer 310. The fixed layer 310 may include a cobalt-iron-boron (CoFeB) film. The fixed layer 310 may also include other ferromagnetic material layers or multilayers, such as CoFeTa, NiFe, Co, CoFe, CoPt, CoPd, FePt, or any alloy of Ni, Co and Fe.

A TMR enhancement layer of the fixed layer 310 abutting the barrier layer 320 may be formed of a material, such as CoFeB, that provides a crystalline orientation for the barrier layer 320. As with the seed layer 306, the material in the fixed layer 310 provides a template for subsequent layers to be grown in a specific crystalline orientation. This orientation may be in any direction within the Miller index system, but is often in the (100) (or (001)) crystal orientation.

The barrier layer 320 (also referred to as a tunnel barrier layer) is formed on the fixed layer 310. The barrier layer 320 provides a tunnel barrier for electrons travelling between the fixed layer 310 and the free layer 330. The barrier layer 320, which may include magnesium oxide (MgO), is formed on the fixed layer 310 and may have a crystalline structure. The crystalline structure of the barrier layer 320 may be in the (100) direction. The barrier layer 320 may include other elements or other materials, such as aluminum oxide (AlO), aluminum nitride (AlN), aluminum oxynitride (AlON), or other non-magnetic or dielectric material. The thickness of the barrier layer 320 is selected so that electrons can tunnel from the fixed layer 310 through the barrier layer 320 to the free layer 330 when a biasing voltage is applied to the MTJ structure 300.

The free layer 330, which may be cobalt-iron-boron (CoFeB), is formed on the barrier layer 320. The free layer 330, when initially deposited on the barrier layer 320, is an amorphous structure. That is, the free layer 330 does not have a crystalline structure when initially deposited on the barrier layer 320. The free layer 330 is also an anti-ferromagnetic layer or multilayer material, which may include similar anti-ferromagnetic materials as the fixed layer 310 or may include different materials.

In this configuration, the free layer 330 includes an anti-ferromagnetic material that is not fixed or pinned in a specific magnetic orientation. The magnetization orientation of the free layer 330 is able to rotate to be in a parallel or an anti-parallel direction to the pinned magnetization of the fixed layer 310. A tunneling current flows perpendicularly through the barrier layer 320 depending upon the relative magnetization directions of the fixed layer 310 and the free layer 330.

A cap layer 350 is formed on the free layer 330. The cap layer 350 may be a dielectric layer, or other insulating layer. The cap layer 350 helps reduce the switching current density that switches the MTJ structure 300 from one orientation (e.g., parallel) to the other (e.g., anti-parallel) and improves perpendicular magnetic anisotropy. The cap layer 350, which may also be referred to as a capping layer, may be an oxide, such as, for example, amorphous aluminum oxide (AlOx) or amorphous hafnium oxide (HfOx). The cap layer 350 may also be other materials, such as magnesium oxide (MgO) or other dielectric materials without departing from the scope of the present disclosure.

The second electrode 308 is formed on the cap layer 350. In one configuration, the second electrode 308 includes tantalum. Alternatively, the second electrode 308 includes any other suitable conductive material for electrical connection of the MTJ structure 300 to other devices or portions of a circuit. Formation of the second electrode 308 on the cap layer 350 completes the MTJ structure 300.

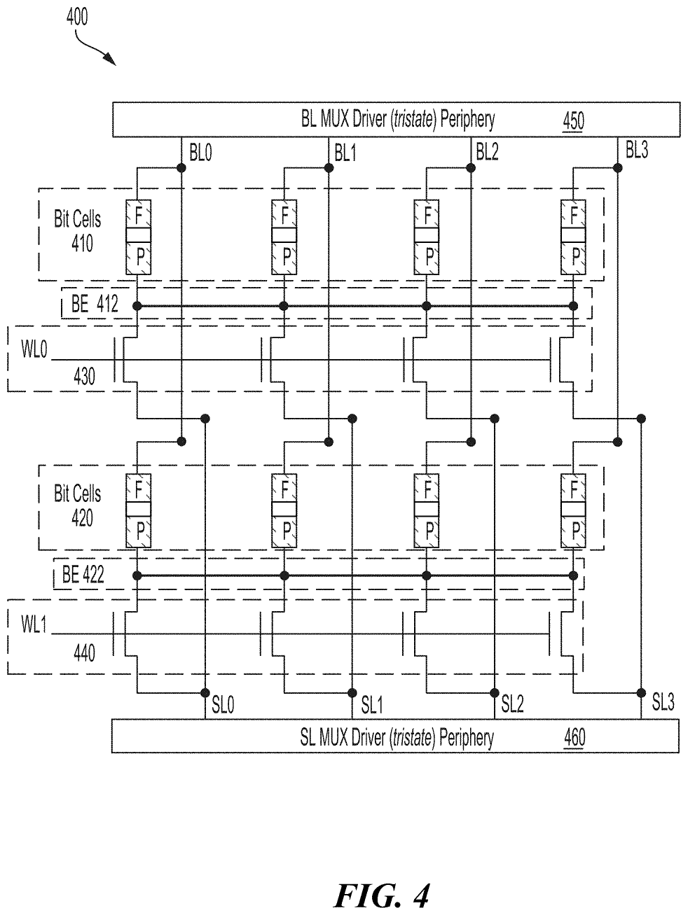

FIG. 4 is a block diagram of a magnetic random access memory (MRAM) array configured for high performance integration, according to aspects of the present disclosure. An MRAM array 400 is configured in a two wordline (WL0, WL1) by four bit/source line (BL0/SL0, BL1/SL1, BL2/SL2, BL3/SL3) configuration. The MRAM array 400 includes a first set of bit cells 410 and a second set of bit cells 420. In this configuration, each of the first bit cells 410 and the second bit cells 420 is composed of a magnetic tunnel junction (MTJ). The MTJ may be configured with a top free layer (F) and a bottom pin layer (P). Alternatively, the MTJ may be configured with a bottom free layer (F) and a top pin layer (P). For example, as shown in FIG. 3, the MTJ may be configured according to the pMTJ 340, including a barrier layer (e.g., 320) between a free layer (e.g., 330) and a pinned (or fixed) layer (e.g., (310). Alternatively, the MTJ may be configured as an in-plane MTJ (iMTJ), including a barrier layer (e.g., 320) between a free layer (e.g., 330) and a pinned (or fixed) layer (e.g., (310).

Referring again to FIG. 4, the MRAM array 400 also includes first wordline (WL0) devices 430, each coupled to an MTJ electrode (e.g., a bottom electrode (BE) 412) of one of the first bit cells 410. In this configuration, the bottom electrodes BE 412 of each of the first bit cells 410 are electrically shorted together. The MRAM array 400 further includes second WL (WL1) devices 440, each coupled to an MTJ electrode (e.g., a bottom electrode (BE) 422) of one of the second bit cells 420. In this configuration, the first WL devices 430 and the second WL devices 440 are implemented as N-type metal oxide semiconductor (NMOS) transistors. In addition, the bottom electrodes BE 422 of each of the second bit cells 420 are also electrically shorted together.

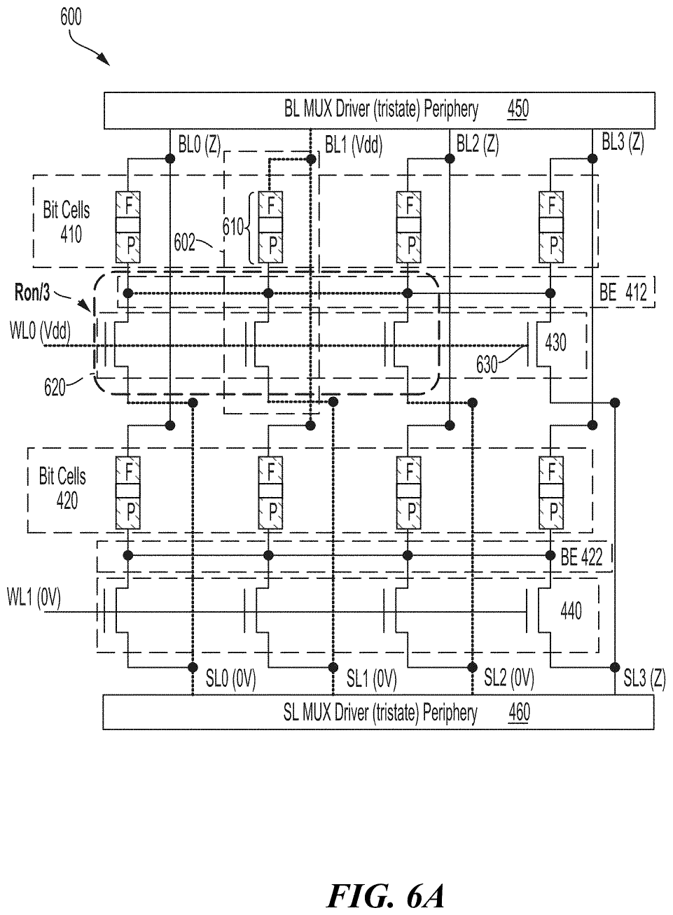

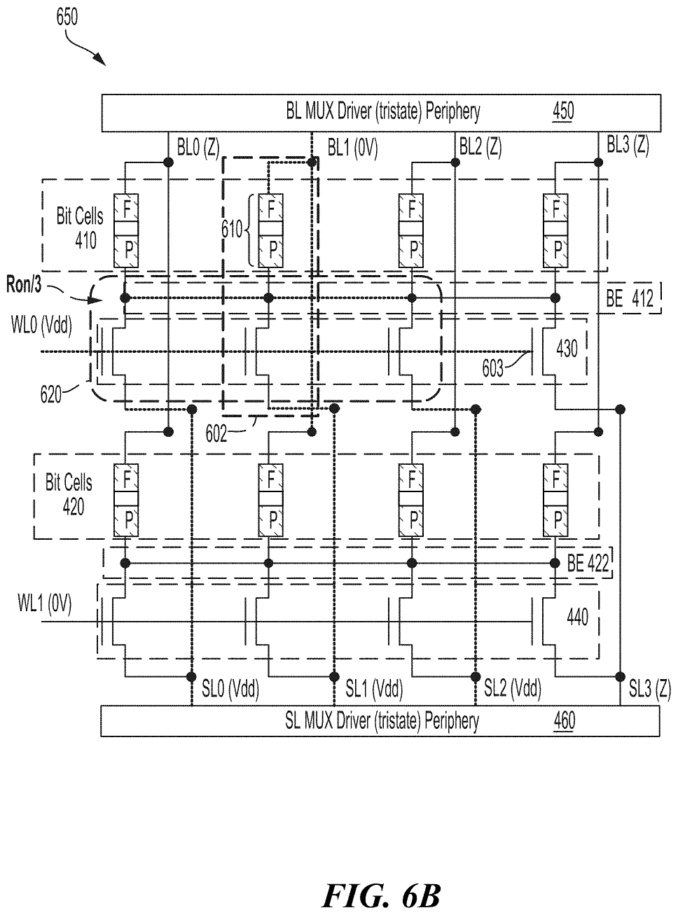

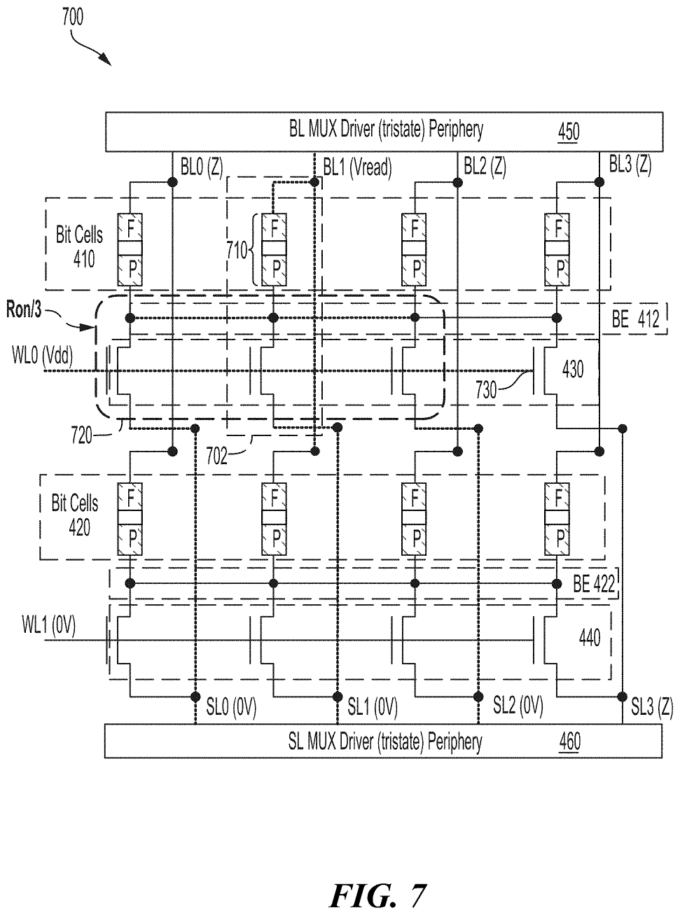

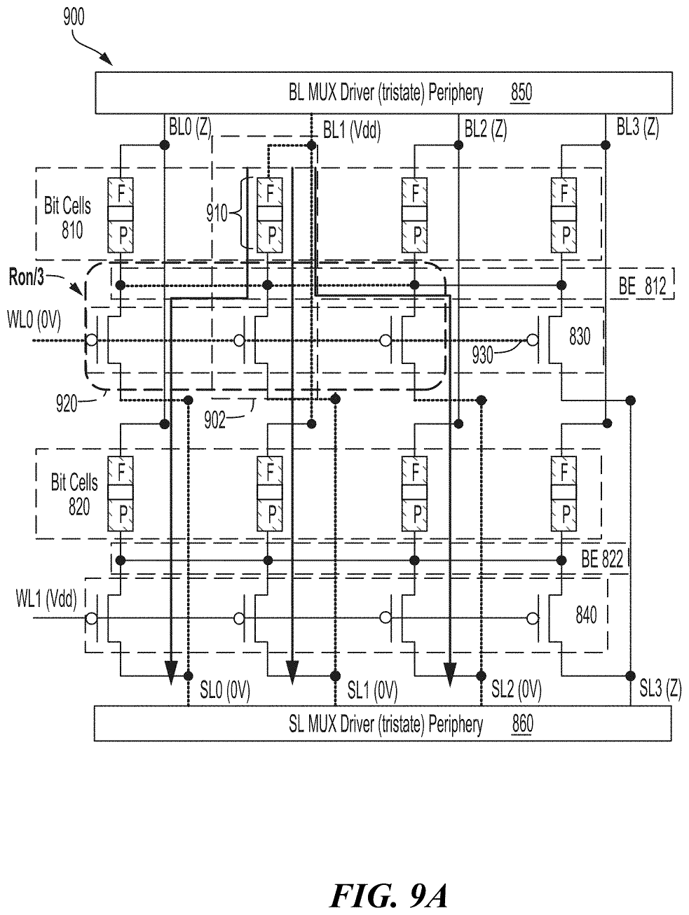

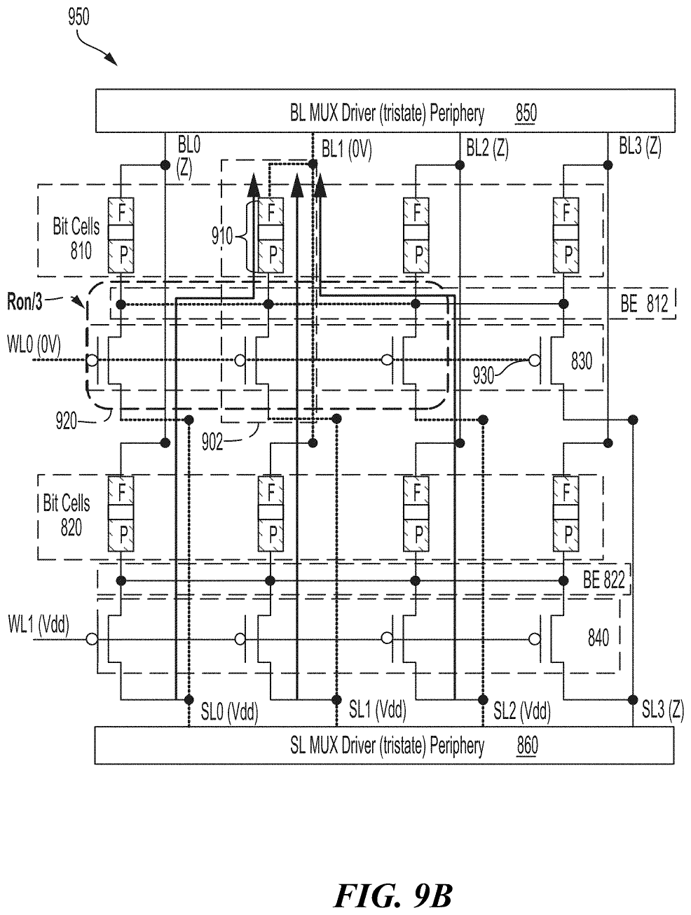

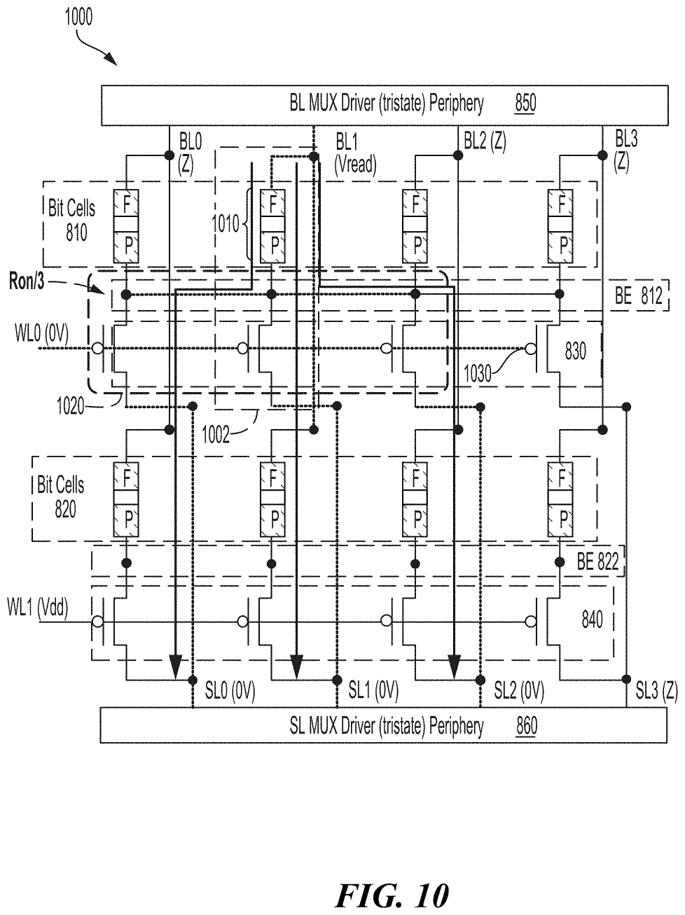

The MRAM array 400 includes a tristate BL driver 450 coupled to each of the first bit cells 410 and the second bit cells 420 via bit lines (e.g., BL0, BL1, BL2, BL3, etc.) The MRAM array 400 further includes a tristate SL driver 460 (e.g., a source line driver) coupled to each of the first bit cells 410 via the first WL devices 430. The tristate SL driver 460 is also coupled to each of the second bit cells 420 via the second WL devices 440. In this configuration, the source lines (e.g., SL0, SL1, SL2, SL3, etc.) from the tristate SL driver 460 are coupled to each of the first WL devices 430 and the second WL devices 440. The tristate BL driver 450 and the tristate SL driver 460 are configured to drive predetermined tristate values to select an MRAM branch(es) to share the first WL devices 430 and/or the second WL devices 440, as described in FIGS. 6A-7 for an NMOS wordline driver configuration and FIGS. 9A-10 for a P-type metal oxide semiconductor (PMOS) wordline driver configuration.

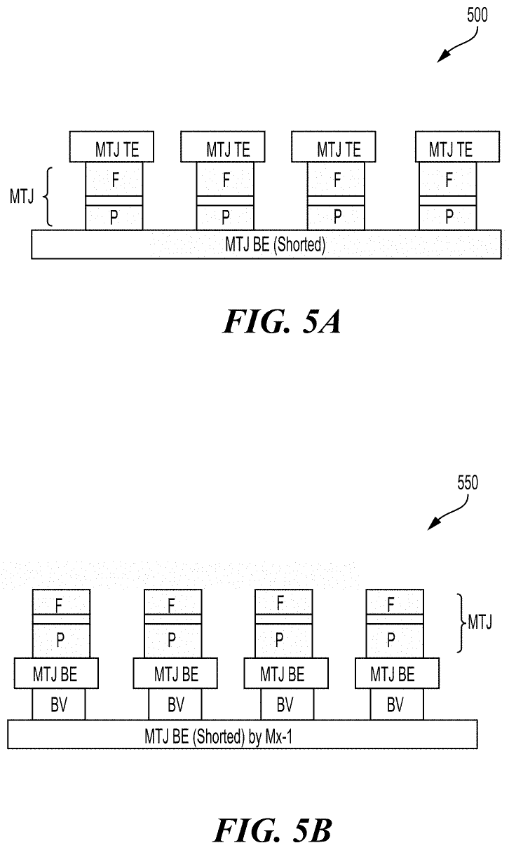

FIGS. 5A and 5B are block diagrams illustrating shorting of MTJ electrodes of an MRAM array, according to aspects of the present disclosure. As shown in FIG. 5A, MTJ cells 500 share a bottom electrode (BE). In other words, the bottom electrodes of each bit cell are shorted together. In this example, a pin layer (P) electrode of the MTJ cells 500 is shorted. In an alternative configuration, a free layer (F) electrode of the MTJ cells 500 is shorted. A top electrode (TE) of the MTJ cells 500 is also shown, which may be shared to short the TE of each of the MTJ cells.

As shown in FIG. 5B, a bottom conductive layer (e.g., bottom metal Mx−1, MTJ is at a metal Mx layer) below the bottom electrode of each bit cell of MTJ cells 550 may be shorted together, instead of the bottom electrode. Alternatively, the bottom conductive layer may be composed of multiple bottom metal layers arranged to short the bottom electrode of the MTJ cells 550 to reduce a metal routing resistance. In this configuration, the bottom metal Mx−1 is contacted to the bottom electrode of the MTJ cells 550 (MTJ BE) through a bottom via (e.g., BV).

FIG. 6A is a block diagram of a magnetic random access memory (MRAM) array configured for a first write operation, according to aspects of the present disclosure. An MRAM array 600 may be configured according to the MRAM array 400 as shown in FIG. 4. The configuration of FIG. 6A illustrates driving of predetermined tristate values for selecting an MRAM branch to share a selected portion 620 of the first WL devices 430. Sharing the selected portion 620 of the first WL devices 430 is performed during a first write operation (e.g., anti-parallel (AP) to parallel (P)) to a bit cell 610 in a selected MRAM branch 602.

Performing the first write operation to the bit cell 610 begins by activating the selected portion 620 of the first WL devices 430. In this example, the selected portion 620 of the first WL devices 430 is activated by driving the wordline WL0 with a supply voltage (e.g., Vdd). In addition, the tristate SL driver 460 drives a zero voltage (0V) on source lines SL0, SL1, and SL2 coupled to the selected portion 620 of the first WL devices 430 to activate the selected portion 620. In this example, the tristate SL driver 460 also drives a high impedance value (Z) on the source line SL3 coupled to a first WL device 630 that is not part of the selected portion 620 of the first WL devices 430. The Z value prevents the current flow through the source line SL3, although the Vdd voltage is applied to wordline WL0 from activating the first WL device 630.

The first write operation to the bit cell 610 continues by selecting the bit cell 610 of a selected MRAM branch 602. In this example, the tristate BL driver 450 selects the bit cell by driving a high impedance (Z) value on bit lines BL0, BL2, and BL3 to deactivate the first bit cells 410 outside of the selected MRAM branch 602. The bit cell 610 of the selected MRAM branch 602 is written (e.g., anti-parallel (AP) to parallel (P)) by driving the supply voltage Vdd on the bit line BL1. An on resistance (Ron) of the first write operation is significantly reduced (e.g., by two-thirds (⅔)) because the selected portion 620 of the WL0 devices 430 are shared during the first write operation to the bit cell 610.

In this aspect of the present disclosure, the tristate BL driver 450 and tristate SL driver 460 enable a variety of configurations for sharing the first WL devices 430. Although described regarding the first WL devices 430, it should be recognized that the second WL devices 440 may be shared by one of the second bit cells 420 during a write operation by driving the supply voltage Vdd to the wordline WL1, rather than the zero voltage (0V) to deactivate the second WL devices 440. Sharing the first WL devices 430 and/or the second WL devices 440 significantly improves the switching/writing of MTJs (e.g., 410, 420) by reducing a wordline on resistance (Ron). In addition, a switching voltage applied to the MRAM array 600 may be increased for fast switching of the first bit cells 410 and/or the second bit cells 420. The selected branch may be varied by driving different tristate values on the source lines and bit lines, as further described with reference to FIG. 6B.

FIG. 6B is a block diagram of a magnetic random access memory (MRAM) array configured for a second write operation, according to aspects of the present disclosure. An MRAM array 650 may also be configured according to the MRAM array 400 as shown in FIG. 4. The configuration of FIG. 6B illustrates driving of predetermined tristate values for selecting an MRAM branch to share a selected portion 620 of the first WL devices 430. Sharing the selected portion 620 of the first WL devices 430 is performed during a second write operation (e.g., parallel (P) to anti-parallel (AP)) to the bit cell 610 in the selected MRAM branch 602.

The second write operation to the bit cell 610 also activates the selected portion 620 of the first WL devices 430 by driving the wordline WL0 with the supply voltage Vdd. In the second write operation, however, the tristate SL driver 460 drives the supply voltage Vdd on the source lines SL0, SL1, and SL2 coupled to the selected portion 620 of the first WL devices 430. In this example, application of the supply voltage Vdd to the source lines SL0, SL1, and SL2 activates the selected portion 620 of the first WL devices 430. The tristate SL driver 460 also drives the high impedance value Z on the source line SL3 coupled to the first WL device 630 for deactivating the first WL device 630.

The second write operation to the bit cell 610 continues by selecting the bit cell 610 of the selected MRAM branch 602. In this example, the tristate BL driver 450 also selects the bit cell 610 by driving the high impedance Z value on the bit lines BL0, BL2, and BL3 to deactivate the first bit cells 410 outside of the selected MRAM branch 602. In the second write operation, the bit cell 610 of the selected MRAM branch 602 is written (e.g., parallel (P) to anti-parallel (AP)) by driving the zero voltage V0 on the bit line BL1. An on resistance (Ron) of the second write operation to the bit cell 610 is significantly reduced (e.g., by two-thirds (⅔)) because the selected portion 620 of the WL0 devices 430 is shared during the second write operation.

FIG. 7 is a block diagram of a magnetic random access memory (MRAM) array configured for a read operation, according to aspects of the present disclosure. An MRAM array 700 may be configured according to the MRAM array 400 as shown in FIG. 4. The configuration of FIG. 7 also illustrates driving of predetermined tristate values for selecting an MRAM branch to share a selected portion 720 of the first WL devices 430. Sharing the selected portion 720 of the first WL devices 430 is performed during a read operation of a bit cell 710 in a selected MRAM branch 702.

Performing the read operation to the bit cell 710 also activates the selected portion 720 of the first WL devices 430. In this example, the selected portion 720 of the first WL devices 430 is activated by driving the wordline WL0 with a supply voltage (e.g., Vdd). The tristate SL driver 460 also drives the zero voltage 0V on the source lines SL0, SL1, and SL2 coupled to the selected portion 720 of the first WL devices 430 for activating the selected portion 720 of the first WL devices 430. In this read operation, the tristate SL driver 460 also drives the high impedance Z value on the source line SL3 coupled to a first WL device 730 that is not part of the selected portion 720 of the first WL devices 430. The high impedance Z value prevents the Vdd voltage applied to wordline WL0 from activating the first WL device 730.

The read operation of the bit cell 710 continues by selecting the bit cell 710 of the selected MRAM branch 702. In this example, the tristate BL driver 450 selects the bit cell 710 by driving the high impedance Z value on bit lines BL0, BL2, and BL3 to deactivate the first bit cells 410 outside of the selected MRAM branch 702. The bit cell 710 of the selected MRAM branch 702 is read by driving a read voltage (Vread) on the bit line BL1. In this configuration, the read voltage Vread is significantly less than a switching voltage (Vswitch). In addition, an on resistance (Ron) of the read operation is significantly reduced (e.g., by two-thirds (⅔)) because the selected portion 720 of the first WL devices 430 is shared during the read operation to the bit cell 710. Consequently, a read tunnel magneto resistance (TMR) is increased according to Equation (1):

$$TMR\_new = \frac{Rap - Rp}{Rp + Ron / 3} > TMR\_old = \frac{Rap - Rp}{Rp + Ron} , \qquad ( 1 )$$

where Rap is anti-parallel resistance and Rp is parallel resistance.

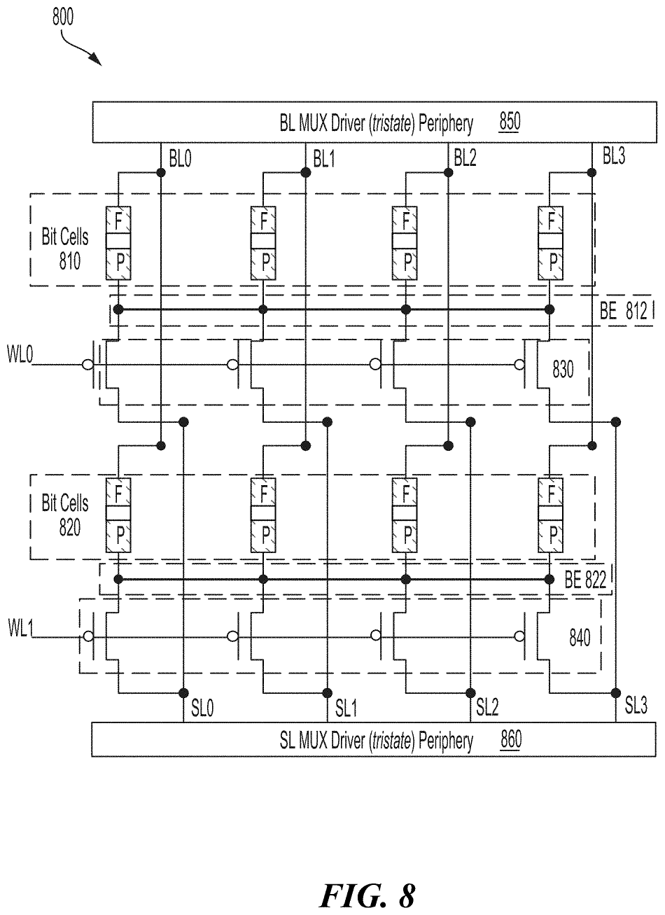

FIG. 8 is a block diagram of a magnetic random access memory (MRAM) array configured for high performance integration, according to aspects of the present disclosure. An MRAM array 800 is also configured in a two wordline (WL0, WL1) by four bit/source line (BL0/SL0, BL1/SL1, BL2/SL2, BL3/SL3) configuration. The MRAM array 800 includes a first set of bit cells 810 and a second set of bit cells 820. In this configuration, the first bit cells 810 and the second bit cells 820 are composed of a magnetic tunnel junction (MTJ) cell. The first bit cells 810 and the second bit cells 820 may also be implemented as the pMTJ 340 of FIG. 3, including a barrier layer (e.g., 320) between a free layer (e.g., 330) and a pinned (or fixed) layer (e.g., 310).

Referring again to FIG. 8, the MRAM array 800 includes first WL devices 830, each coupled to an MTJ electrode (e.g., a bottom electrode (BE) 812) of one of the bit cells 810. The bottom electrodes BE 812 of each of the first bit cells 810 are also electrically shorted. The MRAM array 800 includes second WL devices 840, each coupled to a bottom electrode (BE) 822 of one of the second bit cells 820. In this configuration, however, the first WL devices 830 and the second WL devices 840 are implemented as P-type metal oxide semiconductor (PMOS) transistors. In addition, the bottom electrodes BE 822 of each of the second bit cells 820 are also electrically shorted together.

The MRAM array 800 includes a tristate BL driver 850 coupled to each of the first bit cells 810, and the second bit cells 820 via the bit lines (e.g., BL0, BL1, BL2, BL3, etc.). The MRAM array 800 also includes a tristate SL driver 860 coupled to each of the first bit cells 810 via the first WL devices 830. The tristate SL driver 860 is coupled to each of the second bit cells 820 via the second WL devices 840. In this configuration, the source lines (e.g., SL0, SL1, SL2, SL3, etc.) from the tristate SL driver 860 are coupled to each of the first WL devices 830 and the second WL devices 840. The tristate BL driver 850 and the tristate SL driver 860 are configured to drive predetermined tristate values to select an MRAM branch(es) to share the first WL devices 830 and/or the second WL devices 840, as described with respect to FIGS. 9A, 9B and 10 for a PMOS wordline driver configuration.

FIG. 9A is a block diagram of a magnetic random access memory (MRAM) array configured for a first write operation, according to aspects of the present disclosure. An MRAM array 900 may be configured similar to the MRAM array 800 as shown in FIG. 8. The configuration of FIG. 9A illustrates driving of predetermined tristate values for selecting an MRAM branch to share a selected portion 920 of the first WL devices 830. Sharing the selected portion 920 of the first WL devices 830 is performed during a first write operation (e.g., anti-parallel (AP) to parallel (P)) to a bit cell 910 in the selected MRAM branch 902.

Performing the first write operation to the bit cell 910 begins by activating the selected portion 920 of the first WL devices 830. In contrast to the NMOS configuration shown in FIG. 6A, in the PMOS configuration of FIG. 9A, the selected portion 920 of the first WL devices 830 is activated by driving the wordline WL0 with the zero voltage V0. In addition, the tristate SL driver 860 drives the zero voltage 0V on the source lines SL0, SL1, and SL2 coupled to the selected portion 920 of the first WL devices 830 to activate the selected portion 920. In this example, the tristate SL driver 860 also drives the high impedance Z value on the source line SL3 coupled to a first WL device 930 that is not part of the selected portion 920 of the first WL devices 830. The high impedance Z value prevents current flow in the source line SL3, although the zero voltage V0 is applied to wordline WL0 from activating the first WL device 930.

The first write operation to the bit cell 910 continues by selecting the bit cell 910 of the selected MRAM branch 902. In this example, the tristate BL driver 850 selects the bit cell 910 by driving the high impedance Z value on bit lines BL0, BL2, and BL3 to deactivate the first bit cells 810 outside of the selected MRAM branch 902. The bit cell 910 of the selected MRAM branch 902 is written (e.g., anti-parallel (AP) to parallel (P)) by driving the supply voltage Vdd on the bit line BL1. An on resistance (Ron) of the first write operation is significantly reduced (e.g., by two-thirds (⅔)) because the selected portions 920 of the first WL devices 830 are shared during the first write operation to the bit cell 910. Sharing of the first WL devices 830 is graphically illustrated by highlighted arrows in this example.

In this aspect of the present disclosure, the tristate BL driver 850 and tristate SL driver 860 enable a variety of configurations for sharing the first WL devices 830. Although described regarding the first WL devices 830, it should be recognized that the second WL devices 840 may be shared by one of the second bit cells 820 during a write operation by driving the zero voltage 0V to the wordline WL1, rather than the supply voltage Vdd, which deactivates the second WL devices 840. Sharing the first WL devices 830 and/or the second WL devices 840 significantly improves the switching/writing of MTJs (e.g., 810, 820) by reducing a wordline on resistance (Ron). In addition, a switching voltage applied to the MRAM array 900 may be increased for fast switching of the first bit cells 810 and/or the second bit cells 820. The selected branch may be varied by driving different tristate values on the source lines and bit lines, as further described with respect to FIG. 9B.

FIG. 9B is a block diagram of a magnetic random access memory (MRAM) array configured for a second write operation, according to aspects of the present disclosure. An MRAM array 950 may also be configured similar to the MRAM array 800, as shown in FIG. 8. The configuration of FIG. 9B illustrates driving of predetermined tristate values for selecting an MRAM branch to share a selected portion 920 of the first WL devices 830. Sharing the selected portion 920 of the first WL devices 830 is performed during a second write operation (e.g., parallel (P) to anti-parallel (AP)) to the bit cell 910 in the selected MRAM branch 902.

The second write operation to the bit cell 910 activates the selected portion 920 of the first WL devices 830 by driving the wordline WL0 with the zero voltage V0. In the second write operation, however, the tristate SL driver 860 drives the supply voltage Vdd on the source lines SL0, SL1, and SL2 coupled to the selected portion 920 of the first WL devices 830. In this example, application of the supply voltage Vdd to the source lines SL0, SL1, and SL2 activates the selected portion 920 of the first WL devices 830. The tristate SL driver 860 also drives the high impedance Z value on the source line SL3 coupled to the first WL device 930 for deactivating the first WL device 930.

The second write operation to the bit cell 910 continues by selecting the bit cell 910 of selected MRAM branch 902. In this example, the tristate BL driver 850 also selects the bit cell 910 by driving the high impedance Z value on the bit lines BL0, BL2, and BL3 to deactivate the first bit cells 810 outside of the selected MRAM branch 902. In the second write operation, the bit cell 910 of the selected MRAM branch 902 is written (e.g., parallel (P) to anti-parallel (AP)) by driving the zero voltage V0 on the bit line BL1. An on resistance (Ron) of the second write operation to the bit cell 910 is significantly reduced (e.g., by two-thirds (⅔)) because the selected portion 920 of the first WL devices 830 is shared during the second write operation (see highlighted arrows).

FIG. 10 is a block diagram of a magnetic random access memory (MRAM) array configured for a read operation, according to aspects of the present disclosure. An MRAM array 1000 may be configured similar to the MRAM array 800 as shown in FIG. 8. The configuration of FIG. 10 illustrates driving of predetermined tristate values for selecting an MRAM branch to share a selected portion 1020 of the first WL devices 830. Sharing the selected portion 1020 of the first WL devices 830 is performed during a read operation of a bit cell 1010 in a selected MRAM branch 1002.

Performing the read operation to the bit cell 1010 activates the selected portion 1020 of the first WL devices 830. In this example, the selected portion 1020 of the first WL devices 830 is activated by driving the wordline WL0 with the zero voltage V0. The tristate SL driver 860 also drives the zero voltage 0V on the source lines SL0, SL1, and SL2 coupled to the selected portion 1020 of the first WL devices 830 for activating the selected portion 1020 of the first WL devices 830. In this read operation, the tristate SL driver 860 also drives the high impedance Z value on the source line SL3 coupled to a first WL device 1030 that is not part of the selected portion 1020 of the first WL devices 830. The high impedance Z value prevents the zero voltage V0 applied to wordline WL0 from activating the first WL device 1030.

The read operation of the bit cell 1010 continues by selecting the bit cell 1010 of the selected MRAM branch 1002. In this example, the tristate BL driver 850 selects the bit cell 1010 by driving the high impedance Z value on bit lines BL0, BL2, and BL3 to deactivate the first bit cells 810 outside of the selected MRAM branch 1002. The bit cell 1010 of the selected MRAM branch 1002 is read by driving a read voltage (Vread) on the bit line BL1. In this configuration, the read voltage (Vread) is also significantly less than a switching voltage (Vswitch). In addition, an on resistance (Ron) of the read operation is significantly reduced (e.g., by two-thirds (⅔)) because the selected portions 1020 of the first WL devices 830 are shared during the read operation of the bit cell 1010. Consequently, a read tunnel magneto resistance (TMR) is also increased according to Equation (1).

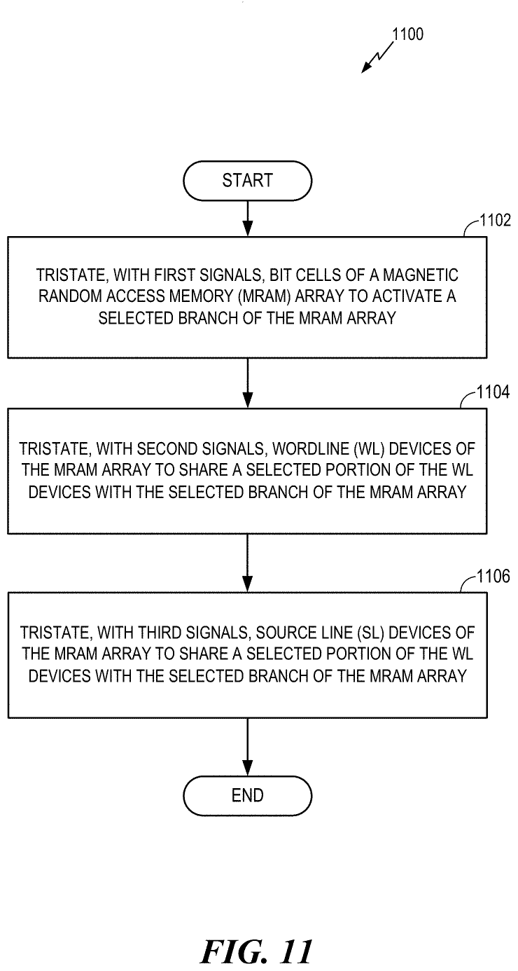

FIG. 11 is a process flow diagram illustrating a method of operating an array of magnetic random access memory (MRAM), according to aspects of the present disclosure. A method 1100 includes, at block 1102, tristating, with first signals, bit cells of the MRAM array to activate a selected branch of the MRAM array. The first signals may be bit line signals. For example, as seen in FIG. 6B, the bit line BL1 is set to the zero voltage 0V, which enables the bit cell 610 of the selected MRAM branch 602. The bit lines BL0, BL2, and BL3 are set to the high impedance Z state, which disables the first bit cells 410 outside the selected MRAM branch 602. As further shown in FIG. 6B, the source lines SL0, SL1, and SL2 are set to the Vdd voltage, which also enables the bit cell 610 of the selected MRAM branch 602. The source lines SL3 is set to the high impedance Z state, which disables the first bit cells 410 outside the selected MRAM branch 602.

At block 1104, the method includes tristating, with second signals, wordline (WL) devices of the MRAM array to share a selected portion of the WL devices with the selected branch. In this example, the second signals may be source line signals. For example, FIG. 6B illustrates tristating of source lines by setting the source lines SL0, SL1, and SL2 to the supply voltage Vdd, while the source line SL3 is set to the high impedance Z value. Due to the shorting of the bottom electrode BE 412 of the first bit cells 410, the selected portions 620 of the first WL devices 430 (e.g., wordline drivers) coupled to the source lines SL0, SL1, SL2 are shorted together.

The method 1100 may also include providing a supply voltage (Vdd) to first WL devices (WL0) of the MRAM array, and supplying zero volts (0V) to second WL devices (WL1) of the MRAM array to limit sharing to the first WL devices (WL0). For example, as shown in FIG. 6B, the combined/shared output of the selected portion 620 of first WL devices 430 is then applied to the bit cell 610 of the first set of bit cells 410 that is associated with the bit BL1. Although FIG. 6B shows a single bit cell sharing the output of the selected portion 620 (e.g., three) of the first WL devices 430, these numbers are merely exemplary. Multiple bit cells can share the combined wordline driver output. Moreover, more or fewer than three of the first WL devices can be shared.

In aspects of the present disclosure, wordline drivers are shared by a selected branch of an MRAM array. Selecting the MRAM branch to share the wordline drivers is performed by driving tristate values of tristate bit line and source line drivers. The shared wordline drivers enable a variety of configurations. For example, the MRAM array may be configured for high performance and reliability. Alternatively, the MRAM array may be configured using a reduced bit cell size with limited MRAM integration reliability. In a configuration using a same (e.g., 1×) bit cell size, high speed performance as well as a large sense window size are realized with no reliability degradation. Wordline overdrive and source line overdrive may be applied to increase small MTJ critical dimension (CD), speed, and performance.

In a configuration using a reduced (e.g., less than ⅓) bit cell size, similar speed, performance, and sense window are achieved with limited reliability. The limited reliability may refer to, for example, a time-dependent dielectric breakdown (TDDB) and a high-temperature operating life (HTOL) of the wordline drivers. In addition, wordline overdrive and source line overdrive may be applied to increase speed and performance. This configuration may use N-type metal oxide semiconductor (NMOS) or P-type MOS (PMOS) transistors as the wordline drivers.

According to an aspect of the present disclosure, an MRAM array is described. In one configuration, the MRAM array includes means for driving wordlines of the MRAM array. The means for driving may be the first WL devices 430 and/or the second WL devices 440 shown in FIGS. 4 and 6A-7 the first WL devices 830 and/or the second WL devices 840 shown in FIGS. 8-10. In another aspect, the aforementioned means may be any module or any apparatus or material configured to perform the functions recited by the aforementioned means.

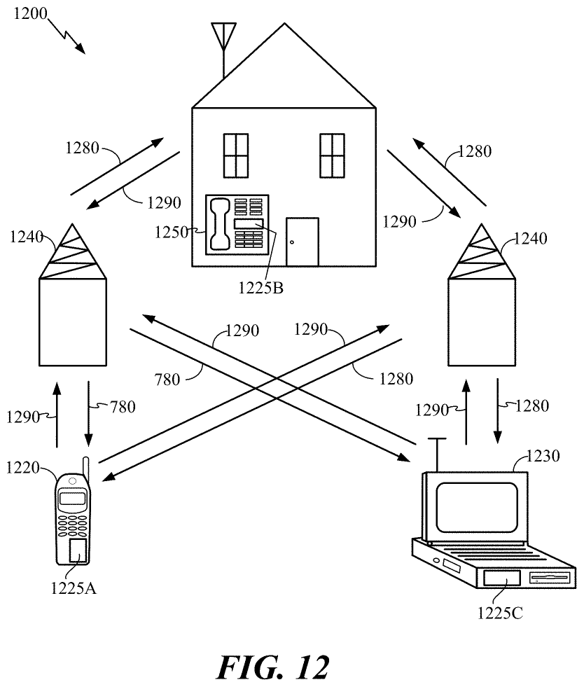

FIG. 12 is a block diagram showing an exemplary wireless communications system 1200 in which an aspect of the disclosure may be advantageously employed. For purposes of illustration, FIG. 12 shows three remote units 1220, 1230, and 1250 and two base stations 1240. It will be recognized that wireless communication systems may have many more remote units and base stations. Remote units 1220, 1230, and 1250 include IC devices 1225A, 1225C, and 1225B that include the disclosed MTJ devices. It will be recognized that other devices may also include the disclosed MTJ devices, such as the base stations, switching devices, and network equipment. FIG. 12 shows forward link signals 1280 from the base station 1240 to the remote units 1220, 1230, and 1250 and reverse link signals 1290 from the remote units 1220, 1230, and 1250 to base stations 1240.

In FIG. 12, remote unit 1220 is shown as a mobile telephone, remote unit 1230 is shown as a portable computer, and remote unit 1250 is shown as a fixed location remote unit in a wireless local loop system. For example, the remote units may be a mobile phone, a hand-held personal communication systems (PCS) unit, a portable data unit such as personal digital assistant (PDA), a GPS enabled device, a navigation device, a set top box, a music player, a video player, an entertainment unit, a fixed location data unit such as meter reading equipment, or a communications device that stores or retrieves data or computer instructions, or combinations thereof. Although FIG. 12 illustrates remote units according to the aspects of the disclosure, the disclosure is not limited to these exemplary illustrated units. Aspects of the disclosure may be suitably employed in many devices, which include the disclosed MTJ devices.

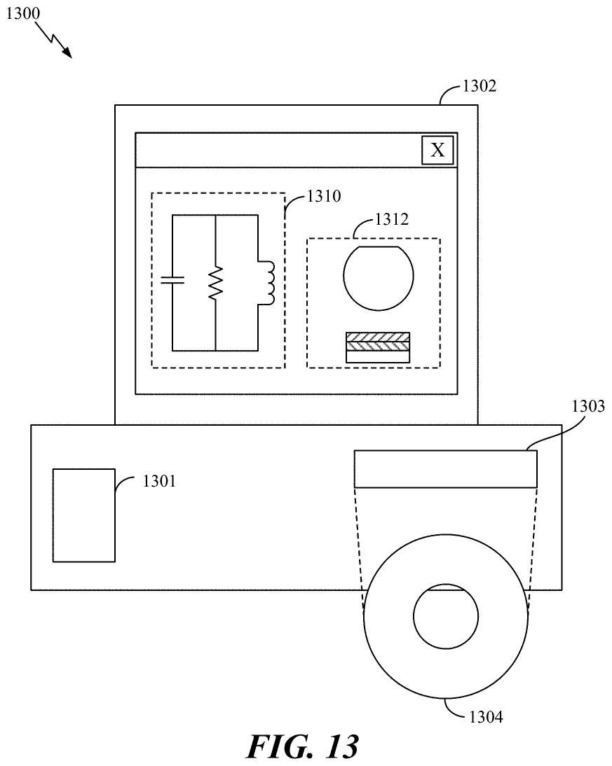

FIG. 13 is a block diagram illustrating a design workstation used for circuit, layout, and logic design of a semiconductor component, such as the MTJ structures disclosed above. A design workstation 1300 includes a hard disk 1301 containing operating system software, support files, and design software such as Cadence or OrCAD. The design workstation 1300 also includes a display 1302 to facilitate design of a circuit 1310 or an MRAM component 1312 such as an MTJ structure in accordance with an aspect of the present disclosure. A storage medium 1304 is provided for tangibly storing the design of the circuit 1310 or the MRAM component 1312. The design of the circuit 1310 or the MRAM component 1312 may be stored on the storage medium 1304 in a file format such as GDSII or GERBER. The storage medium 1304 may be a CD-ROM, DVD, hard disk, flash memory, or other appropriate device. Furthermore, the design workstation 1300 includes a drive apparatus 1303 for accepting input from or writing output to the storage medium 1304.

Data recorded on the storage medium 1304 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1304 facilitates the design of the circuit 1310 or the MRAM component 1312 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core), or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general purpose or special purpose computer, or a general purpose or special purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b, and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

Although the present disclosure provides certain example aspects and applications, other aspects that are apparent to those of ordinary skill in the art, including aspects which do not provide all of the features and advantages set forth herein, are also within the scope of this disclosure. Accordingly, the scope of the present disclosure is intended to be defined only by reference to the appended claims.

What is claimed is:

1. A magnetic random access memory (MRAM) array, comprising:
a plurality of bit cells, each comprising a magnetic tunnel junction (MTJ) including a barrier layer between a free layer and a pinned layer, the plurality of the bit cells shorted together;
a plurality of wordline (WL) devices, each coupled to one of the plurality of the bit cells;
a tristate bit line (BL) driver coupled to each of the plurality of the bit cells; and
a tristate source line (SL) driver coupled to each of the plurality of the bit cells via the plurality of WL devices.

2. The MRAM array of claim 1, in which the tristate BL driver is coupled to the free layer of each of the plurality of the bit cells.

3. The MRAM array of claim 1, in which the tristate BL driver is coupled to the pinned layer of each of the plurality of the bit cells.

4. The MRAM array of claim 1, in which a bottom electrode of each of the plurality of the bit cells is electrically shorted through a bottom electrode.

5. The MRAM array of claim 1, in which the tristate BL driver and the tristate SL driver are configured to drive predetermined tristate values on to the bit cells to activate a selected branch of the MRAM array to share a selected portion of the plurality of the WL devices.

6. The MRAM array of claim 1, in which the plurality of the WL devices comprise N-type metal oxide semiconductor (NMOS) transistors.

7. The MRAM array of claim 1, in which the plurality of the WL devices comprise P-type metal oxide semiconductor (PMOS) transistors.

8. The MRAM array of claim 1, in which the tristate SL driver is directly coupled to each of the plurality of WL devices.

9. A method of operating a magnetic random access memory (MRAM) array, the method comprising:
tristating, with first signals, a plurality of bit cells of the MRAM array to activate a selected branch of the MRAM array; and
tristating, with second signals, wordline (WL) devices of the MRAM array to share a selected portion of the WL devices with the selected branch of the MRAM array.

10. The method of claim 9, further comprising:
providing a supply voltage (Vdd) to first WL devices of the MRAM array; and
supplying zero volts (0V) to second WL devices of the MRAM array.

11. The method of claim 9, in which tristating, with the first signals, comprises
driving a high impedance (Z) value to bit cells outside of the selected branch of the MRAM array; and
driving an active value to a bit cell of the selected branch of the MRAM array.

12. The method of claim 9, further comprising driving a high impedance value, from a source line driver, to control a number of selected portions of the WL devices shared by the selected branch.

13. The method of claim 9, in which the first signals comprise bit line signals and the second signals comprise source line signals.

14. A magnetic random access memory (MRAM) array, comprising:
a plurality of bit cells, each comprising a magnetic tunnel junction (MTJ) including a barrier layer between a free layer and a pinned layer, the plurality of the bit cells shorted together;
means for driving wordlines of the MRAM array, coupled to the plurality of the bit cells;
a tristate bit line (BL) driver coupled to each of the plurality of the bit cells; and
a tristate source line (SL) driver coupled to each of the plurality of the bit cells via the means for driving wordlines of the MRAM array.

15. The MRAM array of claim 14, in which the tristate BL driver is coupled to the free layer of each of the plurality of the bit cells.

16. The MRAM array of claim 14, in which the tristate BL driver is coupled to the pinned layer of each of the plurality of the bit cells.

17. The MRAM array of claim 14, in which a bottom electrode of each of the plurality of the bit cells is electrically shorted through a bottom electrode.

18. The MRAM array of claim 14, in which the tristate BL driver and the tristate SL driver are configured to drive predetermined tristate values on to the bit cells to activate a selected branch of the MRAM array to share a selected portion of the plurality of the WL devices.

19. The MRAM array of claim 14, in which the plurality of the WL devices comprise N-type metal oxide semiconductor (NMOS) transistors.

20. The MRAM array of claim 14, in which the plurality of the WL devices comprise P-type metal oxide semiconductor (PMOS) transistors.
